(19) United States
(12) Patent Application Publication
(10) Pub. No.: US 2015/0275395 A1
(43) Pub. Date: Oct. 1, 2015

(54) SUSCEPTOR FOR EPITAXIAL GROWING AND METHOD FOR EPITAXIAL GROWING

(71) Applicant: LG SILTRON INC., Gumi-si Gyeongsangbuk-do (KR)

(72) Inventor: Yu-Jin Kang, Chilgok-gun Gyeongsangbuk-do (KR)

(73) Assignee: LG SILTRON INC., Gyeongsangbuk-do (KR)

(21) Appl. No.: 14/436,425

(22) PCT Filed: Oct. 16, 2013
(86) PCT No.: PCT/KR2013/009261

§ 371 Date: Apr. 16, 2015

(30) Foreign Application Priority Data
Oct. 16, 2012 (KR) 10-2012-0114743
Oct. 11, 2013 (KR) 10-2013-0121572

(51) Int. Cl. C30B 25/12; C30B 29/06; H01L 21/687; C30B 25/16

(52) U.S. Cl. CPC C30B 25/12; C30B 25/165; C30B 29/06; H01L 21/68785; H01L 21/68735

(57) ABSTRACT

The present disclosure relates to a susceptor for epitaxial growing, which is for manufacturing an epitaxial wafer made by performing a reaction of a wafer and a source gas inside a chamber and growing an epitaxial layer, comprising: a pocket provided with an opening on which the wafer is arranged; a ledge portion for supporting the wafer; and a gas control member positioned on the outer circumferential portion of the upper surface of the susceptor opening, wherein the gas control member comprises a first gas control member which is formed on a predetermined area opposite a crystalline direction of the wafer (110), a second gas control member which is formed on a predetermined area opposite the crystalline direction of the wafer (100), and a third gas control member which is formed between the first gas control member and the second gas control member, wherein the first gas control member, the second gas control member, and the third gas control member are formed so that the size of an area formed along the circumference of the wafer are different from each other, wherein the first, second, and third gas control members are formed so that tilt angles thereof from the center of the wafer toward a susceptor direction are different from each other for changing the flow of the gas. As a result, gas flow can be controlled by forming the area on which devices for increasing/decreasing gas flow around the outer circumferential portion of the susceptor (gas control members) differently, thereby reducing the difference in an epilayer on the edge portions of the wafer when forming the epitaxial layer on the semiconductor wafer.

### TECHNICAL FIELD

The present disclosure relates to a susceptor for manufacturing an epitaxial wafer, and more particularly, to a susceptor for controlling flatness of an edge portion of a wafer.

### BACKGROUND ART

A silicon epitaxial wafer is manufactured by vapor-growing a silicon epitaxial layer on a silicon wafer, wherein the silicon wafer is doped with impurities such as boron (B) to have low specific resistance and the silicon epitaxial layer is doped with less impurities to have high specific resistance. Such a silicon epitaxial wafer has a high gathering capability, a low latch-up characteristic, and a slip-resistant characteristic at a high temperature, and is thus widely used to manufacture not only a MOS device but also an LSI device.

Quality assessment items for such an epitaxial wafer may include flatness and a particle contamination level for assessing a surface of the epitaxial wafer including a substrate and an epitaxial layer and thickness uniformity, specific resistance, uniformity thereof, metal contamination and slip dislocation of the epitaxial layer for assessing the epitaxial layer itself.

While a semiconductor device is manufactured on an epitaxial wafer, the flatness greatly affects a photolithography process, a chemical mechanical polishing (CMP) process, and a bonding process for a silicon on insulator (SOI) wafer. In particular, an edge roll-off phenomenon in which an edge of a wafer is rolled up or down greatly affects defocus at the photolithography process, polishing uniformity at the CMP process, and defective bonding at the SOI bonding process. As a diameter of a wafer is increased to at least 300 mm, the flatness of an edge of a wafer becomes more important for the quality assessment items of an epitaxial wafer. Therefore, it is necessary to find a cause of distortion of the flatness of an edge of an epitaxial wafer.

A semiconductor wafer which is to be a substrate is mounted in a chamber and is rotated at a predetermined rotation speed while forming an epitaxial layer, so that an overall uniform thickness of a layer is achieved. Therefore, a crystal orientation of a wafer is constantly changed with respect to an epitaxial manufacturing device. That is, since the wafer is fixed to a susceptor having a pocket, the crystal orientation of the wafer is constantly fixed with respect to the susceptor.

Since the wafer is rotated while being placed on the susceptor, the thickness of an edge of the wafer may periodically increase or decrease according to the crystal orientation.

FIG. 1 is a diagram illustrating a crystal orientation of a wafer, and FIG. 2 is a graph illustrating a thickness of a deposited epitaxial layer according to an orientation of a typical wafer in the case where a susceptor having a constant pocket height for each orientation is used when an epitaxial layer is deposited on the wafer.

Referring to FIG. 1, provided that a three o'clock direction of a wafer 100 is 0 degree, a direction of 0 degree is a <110> crystal orientation, and a 45-degree-rotated direction with respect to the <110> crystal orientation is a <100> crystal orientation. That is, the same crystal orientations as the <110> and <100> crystal orientations appear at every 90 degrees.

FIG. 2 shows a portion where a deviation of the thickness of the epitaxial layer deposited according to the orientation of the wafer of FIG. 1 is maximized. According to a result of evaluation with respect to a wafer having a diameter of 300 mm, the thickness of the epitaxial layer of an edge portion at a distance of 149 mm from a center of the wafer is largest in the <110> orientation near 180 degrees of the wafer, and is smallest in the <100> orientation near 135 degrees and 225 degrees.

A growing rate of the epitaxial layer varies with a characteristic of a crystal surface according to a wafer orientation, and a deviation of the thickness of the epitaxial layer of the edge portion of the wafer occurs.

As a result, the growing rate of the epitaxial layer is relatively increased in the <110> crystal orientation of the wafer, but is relatively decreased in the <110>crystal orientation of the wafer.

Therefore, the edge portion of the wafer has a section where the deviation of the thickness of the epitaxial layer occurs at intervals of 45 degrees. As the deviation of the thickness becomes more serious, the quality of the wafer is more seriously degraded, and more problems occur in terms of formation of a semiconductor device.

### DISCLOSURE OF THE INVENTION

### Technical Problem

Embodiments provide a susceptor for uniformly controlling a thickness of an edge portion of an epitaxial wafer to improve flatness of a surface of the epitaxial wafer.

### Technical Solution

In one embodiment, a susceptor for epitaxial growth for manufacturing an epitaxial wafer on which an epitaxial layer is grown through reaction between a wafer and a source gas in a chamber includes a pocket having an opening formed therein, the wafer being disposed in the opening, a ledge part supporting the wafer, and a gas regulating member formed on an outer circumferential portion of an upper surface of the opening of the susceptor, wherein the gas regulating member includes a first gas regulating member formed on a predetermined region facing a <110> crystal orientation of the wafer, a second gas regulating member formed on a predetermined region facing a <100> crystal orientation of the wafer, and a third gas regulating member formed between the first gas regulating member and the second gas regulating member, wherein the first to third gas regulating members are formed such that regions thereof formed along a circumference of the wafer have different sizes, wherein the first to third gas regulating members are formed so as to have different inclinations in a direction from a center of the wafer to the susceptor to change a gas flow rate.

### Advantageous Effects

According to the present disclosure, since gas flow rate increasing or decreasing devices (gas regulating members) are formed on different regions on the circumferential portion of the susceptor, the deviation of the thickness of the epitaxial layer of the edge portion of the wafer may be reduced when the epitaxial layer is formed on the semiconductor wafer.

Furthermore, since gas flow rate increasing or decreasing devices (gas regulating members) are formed on different regions on the circumferential portion of the susceptor, the deviation of the thickness of the epitaxial layer of the edge portion of the wafer may be reduced when the epitaxial layer is formed on the semiconductor wafer.

Moreover, since the height or the angle of the gas regulating member is changed according to the crystal orientation of the wafer, the flow rate of a gas may be accurately controlled for each section of the wafer, and thus the thickness of the epitaxial layer of the edge portion of the wafer may be rendered uniform.

In addition, according to the susceptor provided with the gas regulating member of an embodiment, a semiconductor wafer with a uniform flatness may be provided, so that the quality and the production yield of a semiconductor wafer may be improved.

### BRIEF DESCRIPTION OF THE DRAWINGS

FIG. 1 is a diagram illustrating a crystal orientation of a semiconductor wafer.

FIG. 2 is a diagram illustrating a thickness of a part of an epitaxial layer according to a crystal orientation of a wafer in the case of using a typical susceptor.

FIG. 3 is a planar view illustrating a region where a thickness of an epitaxial layer of a wafer increases or decreases according to a crystal orientation of a wafer.

FIG. 4 is a diagram illustrating a structure of a susceptor for manufacturing an epitaxial wafer.

FIG. 5 is a graph illustrating a measured thickness of an epitaxial layer of an edge portion of a wafer according to comparative example 1.

FIG. 6 is a planar view illustrating a region where a gas regulating member is formed on a susceptor according to comparative example 2.

FIG. 7 is a graph illustrating a thickness of an epitaxial layer of a wafer with respect to an entire section of an edge portion according to comparative example 2.

FIG. 8 is a graph illustrating a certain region of FIG. 7.

FIG. 9 is a diagram illustrating a region where a gas regulating member is formed on a susceptor according to comparative example 2.

FIG. 10 is a diagram illustrating a region where a gas regulating member is formed on a susceptor according to an embodiment.

FIG. 11 is a planar view illustrating a region where a gas regulating member is formed on a susceptor according to an embodiment.

FIG. 12 is a graph illustrating a thickness of an edge portion of a wafer measured when a gas regulating member according to an embodiment is formed.

FIG. 13 is a graph illustrating a certain region of FIG. 12.

FIG. 14 is a front view of an upper region of a pocket of a susceptor according to an embodiment.

FIG. 15 is a front view of an upper region of a pocket of a susceptor according to another embodiment.

FIG. 16 is a cross sectional view of a susceptor according to another embodiment.

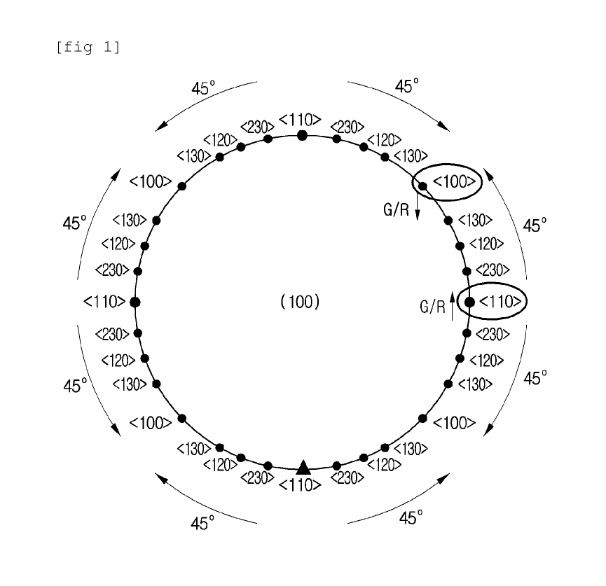

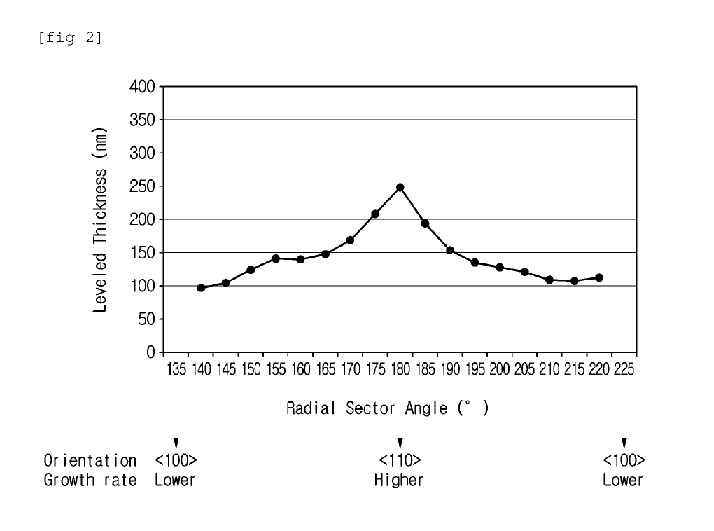

### MODE FOR CARRYING OUT THE INVENTION

Hereinafter, embodiments will be described in detail with reference to the accompanying drawings, but the present disclosure is not limited thereto. Detailed descriptions of known functions or configurations may not be provided herein in order to clarify the point of the present disclosure.

A semiconductor wafer is rotated at a predetermined rotation speed while being supported by a susceptor in an epitaxial manufacturing device, so that an overall uniform thickness of a layer is achieved. In general, a growing rate of an epitaxial layer depends on a flow rate of a gas for epitaxial growth, a concentration of a silicon element, a temperature or the like. Therefore, it is desirable to provide a member for changing the foregoing factors in the vicinity of an inner circumferential surface of an opening of a pocket that supports a wafer. The present embodiment is directed to providing a device and method for controlling a thickness of an epitaxial layer for each crystal orientation using a gas regulating member formed on an upper surface of a susceptor adjacent to an opening thereof so as to control a flow rate of a gas that flows along an edge of a wafer in order to improve flatness of a periphery of the wafer. Furthermore, a region of the gas regulating member formed differently for each crystal orientation is controlled on the basis of comparative examples.

Regarding a silicon single crystal with a <110> crystal orientation, it is known that a growing rate of an epitaxial layer depends on a crystal orientation, and this dependency is more serious at an edge area, and the growing rate is changed. Therefore, at a periphery of a wafer, the thickness of the epitaxial layer increases or decreases at intervals of 90 degrees.

FIG. 3 is a planar view illustrating a region where a thickness of an epitaxial layer of a wafer increases or decreases according to a crystal orientation of the wafer.

Referring to FIG. 3, on the assumption that a direction of 3 o'clock with a <110> crystal orientation with respect to a center of a wafer is 0 degree, the thickness of the epitaxial layer of the wafer is relatively large in regions within a predetermined angle with respect to about 0 degree, about 90 degrees, about 180 degrees and about 270 degrees, and the thickness of the epitaxial layer of the wafer is relatively small in regions within a predetermined angle with respect to about 45 degrees, about 135 degrees, about 225 degrees and 315 degrees. Here, the foregoing angles may vary with a crystal orientation as the wafer is rotated.

Hereinafter, the regions within a predetermined range with respect to about 0 degree, about 90 degrees, about 180 degrees and about 270 degrees are referred to as a higher region, the regions within a predetermined range with respect to about 45 degrees, about 135 degrees, about 225 degrees and 315 degrees are referred to as a lower region, and a region between the higher region and the lower region is referred to as a buffer region. In detail, the higher regions, the lower regions and the buffer regions represent regions on a susceptor on which a gas regulating member is formed to control the flatness of an edge portion of the wafer. That is, the lower region may be defined as a region formed within a predetermined angle with respect to a <110> crystal orientation of the wafer, the higher region may be defined as a region formed within a predetermined angle with respect to a <110> crystal orientation, and the buffer region may be defined as a region between the lower region and the higher region.

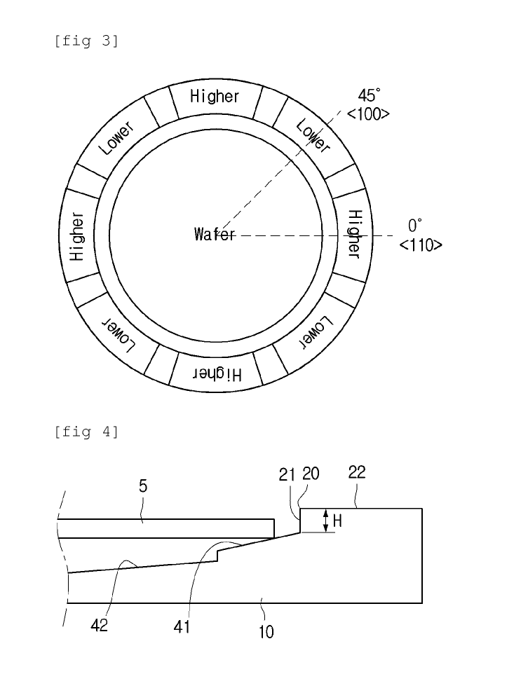

FIG. 4 is a diagram illustrating a structure of a susceptor for manufacturing an epitaxial wafer. Referring to FIG. 4, a semiconductor wafer 5 is supported by a ledge part 41 formed in a pocket 20 that is an opening of a susceptor 10. The pocket 20 may be generally formed in the shape of a circular recess having a flat lower surface, and may include the ledge part 41 and a bottom part 42, wherein the circular recess inside the pocket 20 may accommodate a wafer. That is, the shape of the pocket is defined by an inner circumferential surface 21 and the lower surface, and the ledge part 41 is formed on the lower surface along a circumference of the opening, the edge part 41 having a tapered upper surface extending by as much as a predetermined length from the inner circumferential surface 21 towards an inner circumference side. The ledge part 41 has a tapered upper surface serving as the lower surface of the pocket so as to securely support the semiconductor wafer 5 while minimizing a contact with the semiconductor wafer 5.

The susceptor is disposed in a reaction chamber (not shown), and an epitaxial layer is formed on the wafer 5 while a gas for epitaxial growth is injected to the reaction chamber. Here, a gas jetting hole is provided to an outer circumference side (not shown) of the susceptor, and a source gas flows from an outer circumference of the susceptor towards the inner circumference thereof where the wafer exists. That is, the source gas flows along an upper surface 22 of the opening of the susceptor and arrives at the wafer. A length of the inner circumferential surface of the pocket at which the opening is vertically inclined may be defined as a height H of the pocket, wherein the height H of the pocket is a factor that affects the flow of the gas.

The present disclosure proposes a susceptor structure in which the gas regulating member is formed on the upper surface 22 of the opening of the susceptor so that the flow rate of the gas that flows from the outer circumference of the susceptor towards the wafer is regulated to thereby reduce deviation of the thickness of the edge portion of the wafer.

Hereinafter, a preferred structure of a susceptor will be described through comparison between an example and an embodiment.

### Comparative Example 1

Comparative example 1 is the case where the height H of the pocket of the susceptor is constant for each crystal orientation of the wafer in FIG. 4. The thickness of the epitaxial layer was measured from the edge portion of the wafer after an epitaxial layer deposition process was performed on the wafer.

FIG. 5 is a graph illustrating the thickness of the edge portion of the wafer according to comparative example 1. This graph is evaluation data showing a change in the thickness of the epitaxial layer with respect to an entire section with a diameter of about 149 mm of the edge portion of the wafer having a diameter of about 300 mm.

It may be understood from FIG. 5 that the thickness of the epitaxial layer tends to increase in the <110> crystal orientation, i.e., about 0 degree, about 90 degrees, about 180 degrees and about 270 degrees, and tends to decrease in the <110> crystal orientation, i.e., about 45 degrees, about 135 degrees, about 225 degrees and about 315 degrees. With respect to the entire section of the edge portion of the wafer at a position of a 149 mm diameter, a maximum deviation of the thickness of the epitaxial layer was about 173.44 mm.

### Comparative Example 2

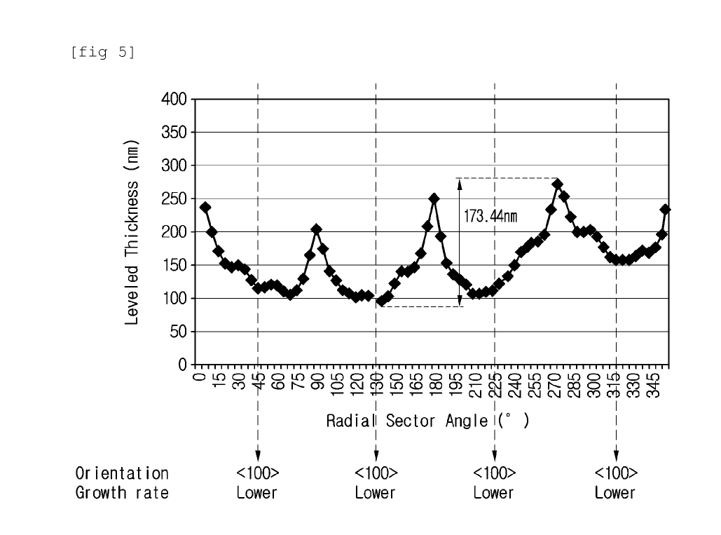

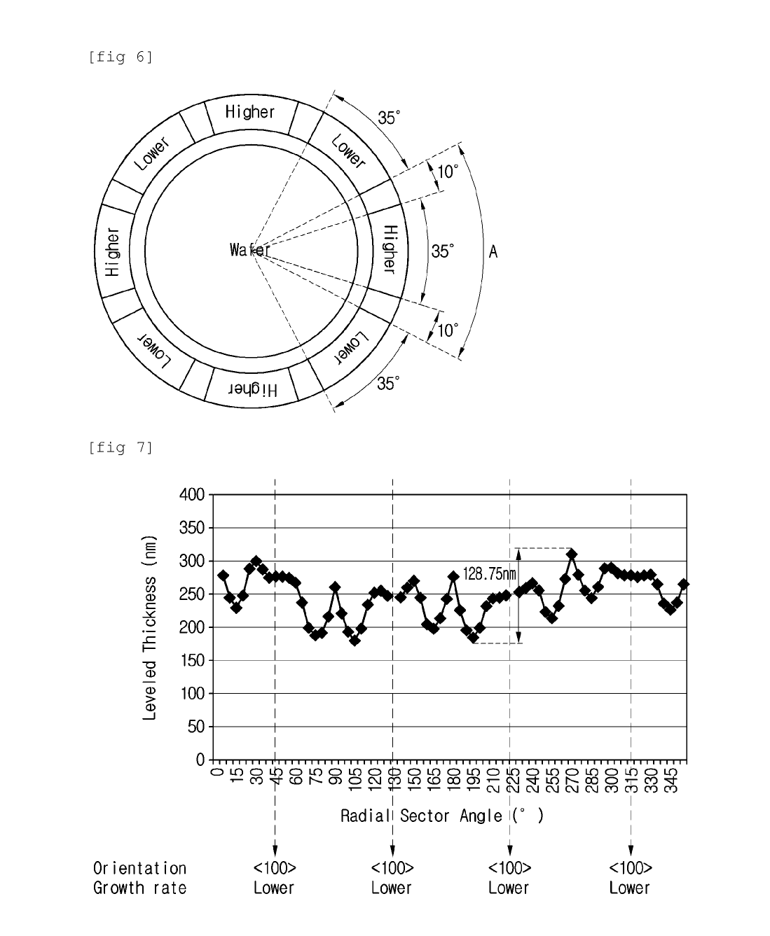

FIG. 6 is a planar view illustrating a region where the gas regulating member is formed on the susceptor according to comparative example 2.

Referring to FIG. 6, a first gas regulating member for reducing a gas flow may be provided to the higher region formed within a predetermined angle with respect to the <110> crystal orientation of the wafer, and a second gas regulating member for increasing a gas flow may be provided to the lower region formed within a predetermined angel with respect to the <110> crystal orientation of the wafer. Furthermore, a third gas regulating member may be provided to the buffer region between the lower region and the higher region, and may have a height different so that a gas fluidly flows between the first and second gas regulating members.

For comparative example 2, a region on the susceptor formed within about 35 degrees with respect to the center of the wafer was set as the higher region, a region formed within about 35 degrees with respect to the center of the wafer was set as the lower region, and a region formed within about 10 degrees between the higher region and the lower region was set as the buffer region, and the gas regulating members were formed for respective regions. The thickness of the epitaxial layer was measured from the edge portion of the wafer after the epitaxial deposition process was performed on the wafer. That is, for comparative example 2, the higher regions and the lower regions were formed to have the same scope and to be symmetrical to each other with respect to the buffer region.

In detail, the pocket height H of the lower region may be about 0.8 mm, the pocket height H of the higher region may be about 1.0 mm, and the pocket height H of the buffer region may be an arbitrary value between those of the lower region and the higher region.

Here, the pocket height H may include a height of a gas regulating member. In detail, the pocket height H may include a height of the first gas regulating member formed on the higher region, a height of the second gas regulating member formed on the lower region, or a height of the third gas regulating member formed on the buffer region.

FIG. 7 is a graph illustrating the thickness of the epitaxial layer of the wafer with respect to the entire section of the edge portion according to comparative example 2. Referring to FIG. 7, the deviation of the thickness of the wafer at a position of a 149 mm diameter of the edge portion of the wafer is about 128.75 nm.

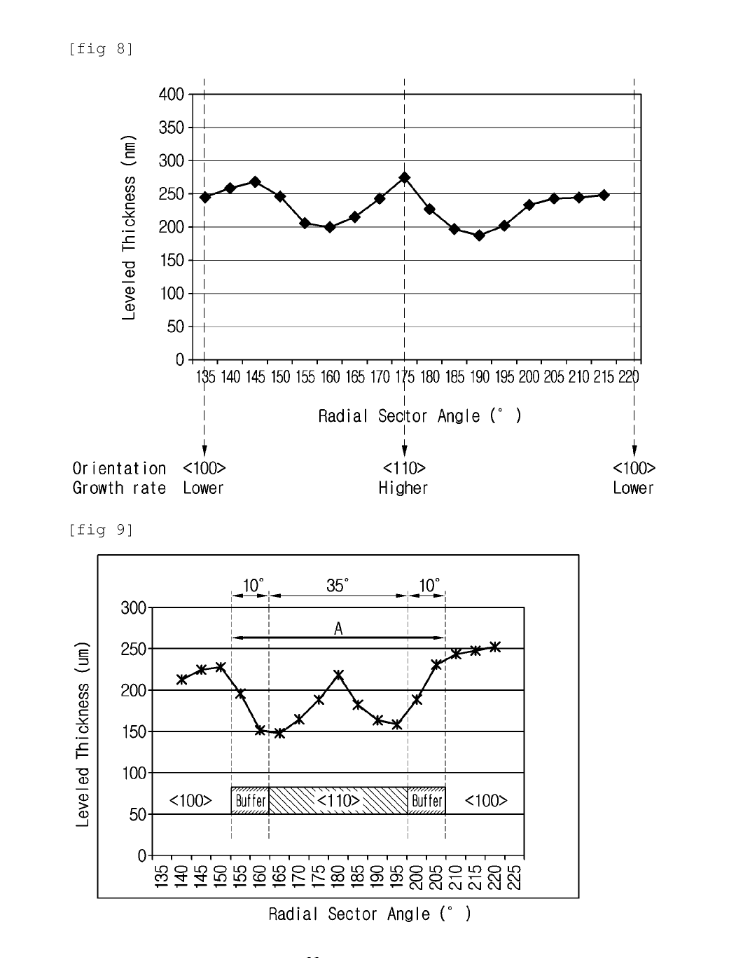

FIG. 8 illustrates a certain region of the edge portion of the wafer evaluated in FIG. 7, more specifically, a section between about 135 degrees and about 225 degrees. It may be understood from FIG. 8 that the thickness of the edge portion of the wafer is largest in the higher region at an angle of about 180 degrees, and tends to increase after decreasing at intervals of about 45 degrees.

In comparative example 2, the higher region and the lower region on which the first and second gas regulating members are arranged to be symmetrical to each other with respect to the buffer region while having an angle of about 35 degrees, in order to deposit the epitaxial layer on the wafer. In comparison to comparative example 1 in which the gas regulating member is not formed, the deviation of the thickness of the entire region of the edge portion of the wafer is reduced, but the quality on the thickness deviation of the edge portion currently required for a semiconductor wafer is not still satisfied.

### Embodiment

Described below is an embodiment in which the higher region on which the first gas regulating member is formed and the lower region on which the second gas regulating member is formed are asymmetrically formed with respect to the buffer region.

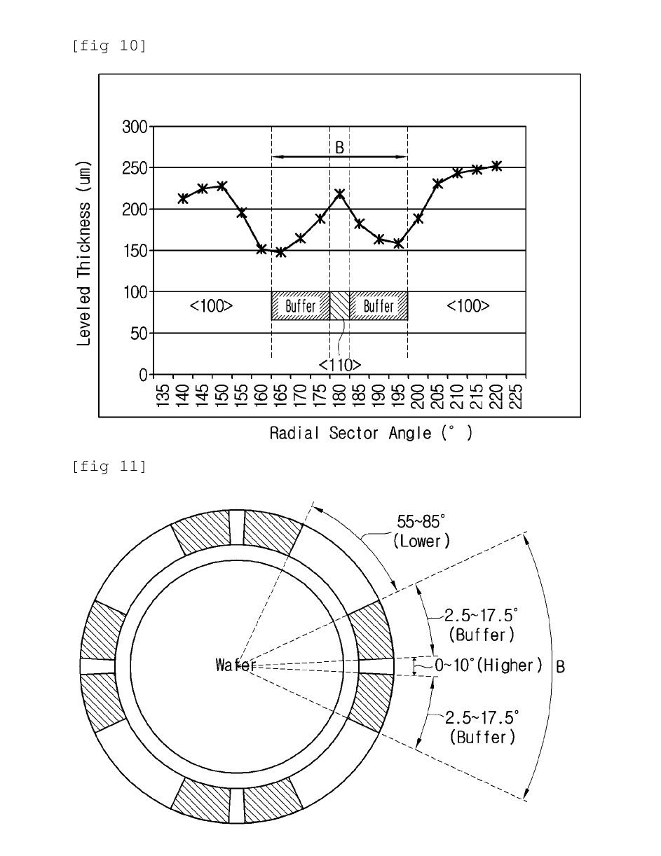

FIG. 9 is a diagram illustrating a region where the gas regulating member is formed on the susceptor according to comparative example 2, and FIG. 10 is a diagram illustrating a region where the gas regulating member is formed on the susceptor according to the embodiment. The embodiment will be described with reference to FIGS. 9 and 10.

FIG. 9 illustrates the thickness of a certain region of the wafer on the susceptor of comparative example 2, more specifically, a region corresponding to an angle between about 135 degrees and about 225 degrees as illustrated in FIG. 8. It may be understood from FIG. 9 that the thickness of the edge portion of the wafer is largest at the center of the higher region of the <110> crystal orientation, and is smallest at a boundary between the buffer region and the higher region. It may be understood from the graph of FIG. 7 that this tendency occurs over the entire section of 360 degrees at intervals of about 90 degrees.

In the present disclosure, in order to more reduce the deviation of the wafer thickness due to this tendency, scopes of the higher region, the lower region and the buffer region are set according to the wafer thickness of comparative example 2.

That is, in a center portion of the <110> crystal orientation where the thickness of the epitaxial layer of the wafer is relatively large, the higher region may be defined within an angle of from about 0 degree to about 10 degrees in order to reduce the thickness of the epitaxial layer, and the first gas regulating member for reducing a gas flow rate may be formed on the higher region.

Furthermore, in a region B where the thickness of the epitaxial layer is reduced with respect to the higher region, the buffer region on which the third gas regulating member is to be formed is set so as to gradually increase the thickness of the epitaxial layer. Furthermore, the lower region may be disposed at an outer circumference of the buffer region. That is, the higher region or the lower region is formed within an angle of about 35 degrees according to comparative example 2, but it is desirable that the region B that is a combination of the higher region and the buffer region is formed within an angle of about 35 degrees according to the present embodiment.

FIG. 11 is a planar view illustrating a region where the gas regulating member is formed on the susceptor according to the embodiment.

Referring to FIG. 11, the higher regions where the first gas regulating member is formed may be formed on the susceptor at intervals of 90 degrees within an angle of about 0 degree to about 10 degrees. The buffer regions adjacent to the higher region may be formed on both sides of the higher region within an angle of about 2.5 degrees to about 17.5 degrees. Furthermore, the lower regions adjacent to the buffer regions may be formed on the susceptor at intervals of 90 degrees within an angle of about 55 degrees to about 85 degrees. That is, according to the present embodiment, the higher region and the lower region are asymmetrically formed with respect to the buffer region.

FIG. 12 is a graph illustrating the thickness of the edge portion of the wafer in the case of forming the gas regulating member according to the embodiment.

Referring to FIG. 12, the deviation of the thickness is about 83.62 nm with respect to the entire section of a 149 mm diameter of the edge portion of the wafer. This indicates that the thickness of the edge portion of the wafer may be controlled to be smaller than about 128 nm that is the deviation of the thickness of comparative example 2, and the thickness deviation of the position of a 149 mm diameter may be controlled to be less than about 3.25% in comparison to the total thickness of the wafer.

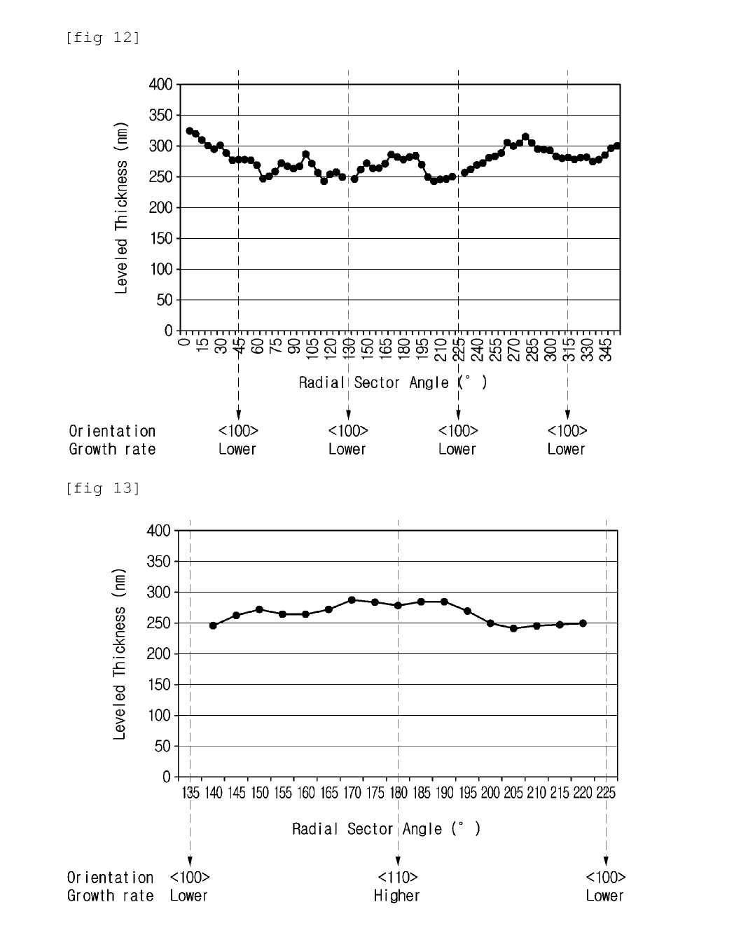

FIG. 13 is a graph illustrating a region within an angle of about 135 degrees to about 225 degrees of the susceptor of FIG. 12. It may be understood from FIG. 13 that the thickness of the wafer at the edge portion due to the higher region, the lower region and the buffer region of the embodiment is more uniform compared to that of comparative example 2, and the thickness deviation at a 90 degree region is about 44.28 nm.

The deviation of the thickness of the edge portion of the wafer is about 173 nm according to comparative example 1 in which the height of the pocket of the susceptor is constant, and the deviation of the thickness of the edge portion of the wafer is about 128 nm according to comparative example 2 in which the height of the pocket of the susceptor varies with a section. That is, the deviation of the thickness of the edge portion of comparative example 2 is improved by about 26% compared to that of comparative example 1.

Furthermore, it may be understood that the deviation of the thickness of the edge portion of the embodiment, which is about 83 nm, is improved by at least about 52% compared to that of comparative example 1. Therefore, according to the embodiment proposed in the present disclosure, the tendency of variation of the wafer thickness is checked according to a crystal orientation, and a region on which the gas regulating member is to be formed is accordingly determined, so that the thickness of the edge portion of the wafer may be more uniformly controlled.

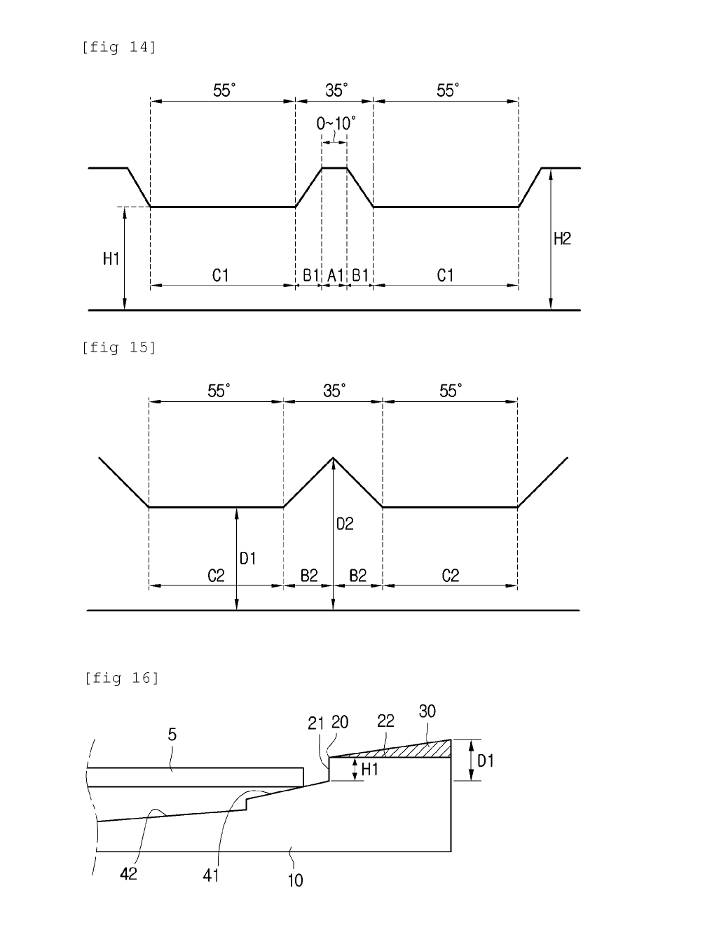

FIGS. 14 and 15 are diagrams illustrating a front view of an upper part of the pocket of the susceptor according to the embodiment. That is, FIGS. 14 and 15 show a front shape of the susceptor according to an angle change of a higher region A1.

Referring to FIG. 14, the higher region A1 of the susceptor is formed within an angle of about 10 degrees having a pocket height H2, and a lower region C1 is formed within an angle of about 55 degrees having a pocket height H1. Furthermore, a buffer region B1 for connecting the higher region and the lower region may be formed within an angle of about 2.5 degrees to about 17.5 degrees having a predetermined inclination.

FIG. 15 specifically illustrates an example in which the higher region is formed with an angle of 0 degree. That is, in this example, in the <110> crystal orientation, the higher region does not exist, and only a buffer region B2 having a predetermined inclined part may be formed so that a gas may uniformly flow.

As described above, the scopes of the higher region, the lower region and the buffer region may be set so that the deviation of the epitaxial layer at the edge portion of the wafer may be reduced.

Meanwhile, as the thickness of the epitaxial layer deposited on the wafer increases, the deviation of the thickness of the epitaxial layer at the edge portion of the wafer tends to increase. As the thickness of the epitaxial layer increases, backside deposition that is anther quality factor increases but may be reduced by increasing the height of the pocket. Therefore, according to the thickness of the epitaxial layer to be formed, the height of the pocket for each region to be formed may be generally increased or decreased.

The height of the pocket of the higher region may be adjusted by coating the susceptor with silicon. Silicon is deposited on the lower region, the buffer region and the higher region on the susceptor according to the thickness of the epitaxial layer to be formed, and, in order to adjust the thickness again, the deposited silicon may be removed through HCL etching.

The present disclosure proposes various examples of the gas regulating member formed for each crystal orientation section of a wafer of which a crystal orientation is divided into sections to set the height of the pocket and a region size.

FIG. 16 is a cross sectional view of a susceptor according to another embodiment.

Referring to FIG. 16, a gas regulating member 30 is formed on the upper surface 22 of the opening of the pocket 20 provided in the susceptor 10. The gas regulating member 30 is inclined in a direction from an end of an outer circumference side of the susceptor to an end side or an edge side of a wafer, and is formed so as to reduce a flow rate of a gas that flows from the outer circumference of the susceptor 10 towards the wafer. That is, the gas regulating member 30 may be formed in the <110> crystal orientation where the epitaxial layer is formed to a relatively large thickness, i.e., may be formed on the higher region. Since an inner circumferential pocket height H2 is larger than an outer circumferential pocket height D2, the flow rate of the gas is reduced in comparison to another region so that the epitaxial layer may be formed to a small thickness.

According to the structure of the gas regulating member 30 illustrated in FIG. 16, the pocket height is gradually changed so that the gas may smoothly flow, and thus the thickness of the epitaxial layer may be more accurately adjusted.

Furthermore, the gas regulating member 30 of FIG. 16 may be simultaneously formed on the higher region and the lower region. In the case of generally increasing the thickness of the epitaxial layer of the edge portion of the wafer, the gas regulating member 30 may be formed on the higher region and the lower region while being inclined in a direction from the susceptor to the center of the wafer in order to increase the flow rate of the gas. Here, an inclination of a first gas regulating member formed on the higher region may be rendered larger than that of a second gas regulating member formed on the lower region, so that the deviation of the thickness of the epitaxial layer of the edge portion of the wafer to be increased may be controlled.

Likewise, in the case of generally decreasing the thickness of the epitaxial layer of the edge portion of the wafer, the gas regulating member 30 may be formed on the higher region and the lower region while being inclined in a direction from the center of the wafer to the susceptor in order to decrease the flow rate of the gas. Here, the inclination of the second gas regulating member formed on the lower region may be rendered larger than that of the first gas regulating member formed on the higher region, so that the deviation of the thickness of the epitaxial layer of the edge portion of the wafer to be decreased may be controlled.

Furthermore, the regulating member may be formed in the shape of a stair, a trapezoid or a triangle in order to increase or decrease the flow rate of the gas.

The various examples of the gas regulating member proposed in the present disclosure may be applied to reduce the deviation of the thickness of the edge part which varies with the orientation of the epitaxial wafer. Although it has been described that the gas regulating member is formed on the higher region, i.e., in the <110> crystal orientation, to decrease the flow rate of the gas and the gas regulating member is formed on the lower region, i.e., in the <110> crystal orientation, to increase the flow rate of the gas, only the gas regulating member for decreasing the flow rate of the gas may be formed in the <110> crystal orientation, and the gas regulating member may not be formed on the buffer region and in the <110> crystal orientation, or vice versa.

That is, since there are various factors that affect the flatness of the edge portion of the wafer, the gas regulating member may be flexibly disposed so that only a location where the deviation of the thickness of the epitaxial layer formed on the wafer is serious may be accurately controlled.

Although the wafer with a diameter of 300 mm has been described as an example, the present disclosure may be applied to wafers with a diameter of 300 mm or more.

According to the susceptor for forming an epitaxial layer of the present disclosure, a gas flow rate increasing or decreasing device (gas regulating member) may be formed with different heights for each crystal orientation at an outer circumferential portion of the susceptor when an epitaxial layer is formed on a semiconductor wafer, so that the thickness of the epitaxial wafer may be rendered uniform along the diameter of the wafer.

Furthermore, since the height or the height difference of the gas regulating member is changed according to the crystal orientation of the wafer, the flow rate of a gas may be accurately controlled for each section of the wafer, and thus the flatness of the epitaxial wafer may be rendered uniform.

Moreover, according to the susceptor of an embodiment, a semiconductor wafer of which an edge portion has a uniform flatness may be provided, so that the quality and the production yield of a semiconductor wafer may be improved.

Although the epitaxial growth on the surface of the silicon wafer 100 has been described as an example, the present disclosure is not limited thereto. For example, the present disclosure may be applied to an epitaxial manufacturing device for any material having an epitaxial growing rate dependent on the crystal orientation or a susceptor used therein. Furthermore, although the <110> and <100> crystal orientations have been described, the present disclosure may be applied to and [100] orientations having the same crystal characteristic.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

### INDUSTRIAL APPLICABILITY

The present embodiment may be applied to an epitaxial growing device for manufacturing an epitaxial wafer, and is thus industrially applicable.

1-13. (canceled)

14. A susceptor for epitaxial growth for manufacturing an epitaxial wafer on which an epitaxial layer is grown through reaction between a wafer and a source gas in a chamber, the susceptor comprising:
a pocket having an opening formed therein, the wafer being disposed in the opening;
a ledge part supporting the wafer; and
a gas regulating member formed on an outer circumferential portion of an upper surface of the opening of the susceptor, wherein:
the gas regulating member comprises a first gas regulating member formed on a predetermined region facing a crystal orientation of the wafer,
a second gas regulating member formed on a predetermined region facing a crystal orientation of the wafer, and a third gas regulating member formed between the first gas regulating member and the second gas regulating member,
the first to third gas regulating members are formed such that regions thereof formed along a circumference of the wafer have different sizes, and
the first gas regulating member is formed on a region where the epitaxial layer of an edge portion of the wafer is deposited to a relatively large thickness, and is formed on the susceptor to have an angle of about 0 degree to about 10 degrees with respect to the crystal orientation.

15. The susceptor of claim 14, wherein the regions of the first and second gas regulating members are asymmetrical to each other with respect to the third gas regulating member.

16. The susceptor of claim 14, wherein the third gas regulating member is formed on a region where a thickness of the epitaxial layer of an edge portion of the wafer is increased or decreased, and is formed within an angle of about 2.5 degrees to about 17.5 degrees at both sides of the first gas regulating member.

17. The susceptor of claim 14, wherein the second gas regulating member is formed on a region where the epitaxial layer of an edge portion of the wafer is deposited to a relatively small thickness, and is formed on the susceptor to have an angle of about 55 degrees to about 80 degrees with respect to the crystal orientation.

18. The susceptor of claim 14, wherein the first to third gas regulating members are formed to different heights on the susceptor to change the gas flow rate.

19. The susceptor of claim 14, wherein the first and second regulating members are formed on the susceptor at intervals of about 90 degrees according to a crystal orientation of the wafer.

20. The susceptor of claim 14, wherein the first gas regulating member is a silicon deposited layer having a predetermined thickness to reduce the gas flow rate, and the second gas regulating member is a silicon deposited layer having a predetermined thickness to increase the gas flow rate.

21. The susceptor of claim 14, wherein the first gas regulating member is a structure inclined in a direction from the center of the wafer to the susceptor to reduce the gas flow rate.

22. The susceptor of claim 14, wherein the second gas regulating member is a structure inclined in a direction from the susceptor to the center of the wafer to increase the gas flow rate.

23. The susceptor of claim 14, wherein the first and second gas regulating members are structures inclined in a direction from the center of the wafer to the susceptor to reduce the gas flow rate, wherein an inclination of the first gas regulating member is larger than that of the second gas regulating member.

24. The susceptor of claim 14, wherein the first to third gas regulating members are formed so as to have different inclinations in a direction from a center of the wafer to the susceptor to change a gas flow rate.
